(19) United States
(12) Patent Application Publication
(10) Pub. No.: US 2026/0215124 A1
(43) Pub. Date: Jul. 23, 2026

(54) DISPLAY DEVICE AND ELECTRONIC DEVICE INCLUDING THE SAME

(71) Applicant: Samsung Display Co., LTD., Yongin-si (KR)

(72) Inventors: Jae Woo LEE, Yongin-si (KR); Tae Ho KIM, Yongin-si (KR); Dong Min LEE, Yongin-si (KR); Seung Jun LEE, Yongin-si (KR); Sun Young JUNG, Yongin-si (KR)

(21) Appl. No.: 19/351,568

(22) Filed: Oct. 7, 2025

(30) Foreign Application Priority Data
Jan. 20, 2025 (KR) 10-2025-0007752

(51) Int. Cl. H10K 59/00; H10K 59/35

(52) U.S. Cl. CPC H10K 59/771; H10K 59/353

(57) ABSTRACT

A display device includes a substrate, a first electrode disposed on the substrate, a second electrode disposed on the first electrode, and a first light-emitting layer disposed between the first electrode and the second electrode and including a first sub-light-emitting layer, a charge generation layer, and a second sub-light-emitting layer, where an area of the first sub-light-emitting layer is larger than an area of the charge generation layer.

This application claims priority to Korean Patent Application No. 10-2025-0007752, filed on Jan. 20, 2025, and all the benefits accruing therefrom under 35 U.S.C. § 119, the content of which in its entirety is herein incorporated by reference.

### BACKGROUND

### 1. Field

The specification relates to a display device and an electronic device including the same.

### 2. Description of the Related Art

Electroluminescence displays may be divided into inorganic light-emitting displays and organic light-emitting displays depending on the material of a light-emitting layer. An active matrix-type organic light-emitting display includes an organic light-emitting diode (“OLED”) that emits light by itself. In addition, the organic light-emitting display has the advantages of fast response speed, high luminous efficiency, high luminance, and wide viewing angle. In the organic light emitting display, the OLED is formed in each pixel. Due to its ability to express a black grayscale level as complete black as well as its fast response speed, excellent luminous efficiency, high luminance and wide viewing angle, the organic light emitting display has excellent contrast ratio and color reproducibility.

### SUMMARY

Features of the specification provide a display device with improved light efficiency.

However, features of the specification are not restricted to the one set forth herein. The above and other features of the specification will become more apparent to one of ordinary skill in the art to which the specification pertains by referencing the detailed description of the specification given below.

According to various embodiments of the specification, a display device includes a substrate, a first electrode disposed on the substrate, a second electrode disposed on the first electrode, and a first light-emitting layer disposed between the first electrode and the second electrode and including a first sub-light-emitting layer, a charge generation layer, and a second sub-light-emitting layer, where an area of the first sub-light-emitting layer is larger than an area of the charge generation layer.

According to various embodiments of the specification, an area of the second sub-light-emitting layer may be larger than the area of the charge generation layer.

According to various embodiments of the specification, the display device may further include a first common layer disposed between the first electrode and the first light-emitting layer, and a second common layer disposed between the first light-emitting layer and the second electrode.

According to various embodiments of the specification, the display device may include a first emission area, a second emission area, and a third emission area spaced apart from each other, a second light-emitting layer disposed in the second emission area, and a third light-emitting layer disposed in the third emission area, where the first light-emitting layer may be disposed in the first emission area.

According to various embodiments of the specification, an area of the first emission area may be larger than an area of the second emission area and an area of the third emission area.

According to various embodiments of the specification, each of the second light-emitting layer and the third light-emitting layer may be disposed between the first common layer and the second common layer, the second light-emitting layer may include a second intermediate layer and a third sub-light-emitting layer, and the third light-emitting layer may include a third intermediate layer and a fourth sub-light-emitting layer.

According to various embodiments of the specification, the second intermediate layer may include a second sub-intermediate layer and a third sub-intermediate layer, and the third intermediate layer may include a fourth sub-intermediate layer and a fifth sub-intermediate layer.

According to various embodiments of the specification, the first light-emitting layer may include a first intermediate layer including the charge generation layer and a first sub-intermediate layer.

According to various embodiments of the specification, the area of the first sub-light-emitting layer and an area of the second sub-light-emitting layer may be larger than an area of the first sub-intermediate layer.

According to various embodiments of the specification, the charge generation layer may include a first charge generation layer and a second charge generation layer disposed between the first charge generation layer and the second sub-light-emitting layer.

According to various embodiments of the specification, the second sub-light-emitting layer includes a first area overlapping the first sub-light-emitting layer, and the first area includes a first sub-area overlapping the charge generation layer.

According to various embodiments of the specification, the first area further includes a second sub-area next (adjacent) to the first sub-area, and a distance from a lower surface of the first sub-light-emitting layer to an upper surface of the second sub-light-emitting layer is greater in the first sub-area than in the second sub-area.

According to various embodiments of the specification, an electronic device includes a processor providing an image signal, a display module receiving the image signal from the processor and displaying an image, and a power module supplying power to the display module, where the display module includes a substrate in which a first emission area, a second emission area, and a third emission area spaced apart from each other are defined, a plurality of first electrodes disposed on the substrate, a first light-emitting layer disposed on a first electrode overlapping the first emission area among the plurality of first electrodes, a second light-emitting layer disposed on a first electrode overlapping the second emission area among the plurality of first electrodes, a third light-emitting layer disposed on a first electrode overlapping the third emission area among the plurality of first electrodes, and a second electrode disposed on the first light-emitting layer, the second light-emitting layer, and the third light-emitting layer, where the first light-emitting layer includes a first sub-light-emitting layer, a charge generation layer, and a second sub-light-emitting layer, and each of the second light-emitting layer and the third light-emitting layer includes a single light-emitting layer.

According to various embodiments of the specification, the second sub-light-emitting layer includes a first area overlapping the first sub-light-emitting layer, and the first area includes a first sub-area overlapping the charge generation layer.

According to various embodiments of the specification, the first area further includes a second sub-area next (adjacent) to the first sub-area, and a distance from a lower surface of the first sub-light-emitting layer to an upper surface of the second sub-light-emitting layer is greater in the first sub-area than in the second sub-area.

According to various embodiments of the specification, an area of the first sub-light-emitting layer may be larger than an area of the charge generation layer.

According to various embodiments of the specification, an area of the second sub-light-emitting layer may be larger than the area of the charge generation layer.

According to various embodiments of the specification, the display device may further include a first common layer disposed between the plurality of first electrodes and the first light-emitting layer to overlap the first emission area, the second emission area, and the third emission area, and a second common layer disposed between the first light-emitting layer and the second electrode to overlap the first emission area, the second emission area, and the third emission area.

According to various embodiments of the specification, the second light-emitting layer and the third light-emitting layer are each disposed between the first common layer and the second common layer, the second light-emitting layer includes a second intermediate layer and a third sub-light-emitting layer, and the third light-emitting layer includes a third intermediate layer and a fourth sub-light-emitting layer.

According to various embodiments of the specification, the second intermediate layer includes a second sub-intermediate layer and a third sub-intermediate layer, and the third intermediate layer includes a fourth sub-intermediate layer and a fifth sub-intermediate layer.

According to the specification, the probability that a leakage current will be generated via a second common layer may be reduced by a second sub-light-emitting layer disposed on a portion of a first charge generation layer disposed on a bank. In addition, the areas of the first charge generation layer and a second charge generation layer which directly contact a first common layer and the second common layer may be reduced.

According to the specification, the probability that a leakage current will be generated via the first common layer may be reduced by a first sub-light-emitting layer disposed on a portion of the second charge generation layer disposed on the bank. In addition, the areas of the second charge generation layer and the first charge generation layer which directly contact the second common layer and the first common layer may be reduced.

According to the specification, a display device may normalize luminous efficiency in a tandem structure. In addition, since the luminous efficiency of the display device is improved, the display device may be driven with lower power.

### BRIEF DESCRIPTION OF THE DRAWINGS

These and/or other features will become apparent and more readily appreciated from the following description of the embodiments, taken in conjunction with the accompanying drawings in which:

FIG. 1A is a perspective view of an embodiment of a display device according to the specification, and FIG. 1B is an enlarged view of portion AA of FIG. 1A;

FIG. 2 is a schematic block diagram of an embodiment of the display device according to the specification;

FIG. 3 is a plan view of an embodiment of a display area according to the specification;

FIG. 4 is a detailed cross-sectional view of a display device including light-emitting elements;

FIG. 5 schematically illustrates light-emitting elements of a display device;

FIG. 6 illustrates FIG. 5 in detail;

FIG. 7 schematically illustrates current leakage due to a deposition position deviation of a first charge generation layer;

FIG. 8A illustrates FIG. 7 in detail, and FIG. 8B is an enlarged view of portion BB of FIG. 8A;

FIG. 9 schematically illustrates current leakage due to a deposition position deviation of a second charge generation layer;

FIG. 10A illustrates FIG. 9 in detail, and FIG. 10B is an enlarged view of portion CC of FIG. 10A;

FIG. 11 schematically illustrates an embodiment of light-emitting elements of a display device according to the specification;

FIG. 12 illustrates FIG. 11 in detail;

FIG. 13 schematically illustrates a case where an error occurs in an embodiment of the deposition position of a first charge generation layer in the display device according to the specification;

FIG. 14 illustrates FIG. 13 in detail;

FIG. 15 schematically illustrates an embodiment of a case where an error occurs in the deposition position of a second charge generation layer in the display device according to the specification;

FIG. 16 illustrates FIG. 15 in detail;

FIG. 17 is a plan view illustrating an embodiment of a deposition margin applied to a display device according to the specification;

FIG. 18 is a plan view illustrating a case where no error occurs in an embodiment of a deposition position in the display device according to the specification;

FIG. 19 is a plan view illustrating a case where an error occurs in an embodiment of the deposition position of a charge generation layer in the display device according to the specification;

FIG. 20 is a plan view illustrating an embodiment of a case where an error occurs in the deposition position of a charge generation layer and the deposition position of a light-emitting layer in the display device according to the specification;

FIG. 21 is a block diagram of an embodiment of an electronic device according to the specification; and

FIG. 22 is a schematic diagram of electronic devices according to various embodiments of the specification.

### DETAILED DESCRIPTION

The advantages and features of the embodiments disclosed herein, and methods of achieving them, will become apparent upon reference to the embodiments described in detail with accompanying drawings. However, the disclosure according to the disclosure is not limited to the embodiments disclosed herein, but will be embodied in many different forms, and these embodiments are provided merely to make the disclosure complete and to fully inform one of ordinary skill in the art to which the disclosure according to the disclosure belongs, and the disclosure according to the disclosure is defined by the scope of the claims.

References to an element or layer as being “on” another element or layer include both cases in which another layer or element is directly on top of or interposed between other elements. Throughout this specification, like reference numerals refer to like components. The shapes, sizes, proportions, angles, numbers, etc. disclosed in the drawings to illustrate embodiments are exemplary and are not intended to be limiting to those shown herein.

Although first, second, or the like are used to describe various components, the components are not limited by these terms. Thus, a first component referred to herein may also be a second component within the technical idea of the disclosure.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

Each of the features of the various embodiments disclosed herein may be combined or combinable with each other, in part or in whole, and may be technically interlocked and operated in a variety of ways, and each embodiment may be practiced independently of or in conjunction with one another.

Specific embodiments will be described below with reference to the accompanying drawings. Configurations that function substantially the same between embodiments are given the same drawing designation and repeated description is omitted.

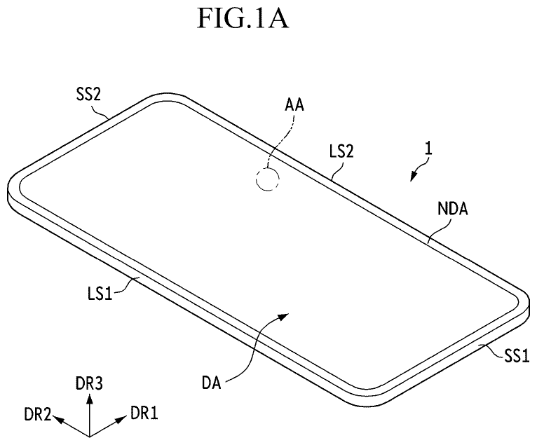

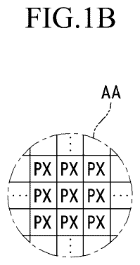

FIG. 1A is a perspective view of an embodiment of a display device 1 according to the specification, and FIG. 1B is an enlarged view of portion AA of FIG. 1A.

In FIG. 1A, a first direction DR1, a second direction DR2, and a third direction DR3 are defined. The first direction DR1 and the second direction DR2 may be perpendicular to each other, the first direction DR1 and the third direction DR3 may be perpendicular to each other, and the second direction DR2 and the third direction DR3 may be perpendicular to each other. It may be understood that the first direction DR1 refers to a horizontal direction in the drawing, the second direction DR2 refers to a vertical direction in the drawing, and the third direction DR3 refers to an up-down direction in the drawing, that is, a thickness direction. In the following specification, unless otherwise specified, a “direction” may refer to both directions extending to both sides along the direction. In addition, when it is desired to distinguish both “directions” extending to both sides, one side is referred to as “one side in the direction,” and the other side is referred to as “the other side in the direction.” In the drawing, a direction in which an arrow is directed is referred to as one side, and a direction opposite to the direction is referred to as the other side. However, directions mentioned in embodiments should be understood as relative directions, and the disclosure is not limited to the mentioned directions.

For ease of description below, in referring to surfaces of the display device 1 or each member constituting the display device 1, one surface facing one side in a direction in which an image is displayed, that is, in the third direction DR3 is also referred to as an upper surface, and a remaining (the other) surface opposite the one surface is also referred to as a lower surface. However, embodiments of the specification are not limited thereto, and the one surface and a remaining (the other) surface of each member may also be also referred to as a front surface and a rear surface or as a first surface and a second surface, respectively. In addition, in describing relative positions of the members of the display device 1, one side in the third direction DR3 may be also referred to as an upper side, and an opposite side in the third direction DR3 may be also referred to as a lower side.

The display device 1 may refer to any electronic device that provides a display screen. In embodiments, the display device 1 may include a mobile phone, a smartphone, a tablet personal computer (“PC”), an electronic watch, a smart watch, a watch phone, a mobile communication terminal, an electronic notebook, an electronic book, a portable multimedia player (“PMP”), a navigation device, a game machine, a digital camera, a television, a notebook computer, a netbook, a monitor, a billboard, and an Internet of things (“loT”) device, all of which provide a display screen. The illustrated embodiment shows an embodiment in which the display device 1 is applied to a portable device such as a tablet PC or a mobile phone.

The planar shape of the display device 1 is not limited. In an embodiment, the planar shape of the display device 1 may be changed to various shapes such as a rectangle, a square, a rhombus, other polygons, a circle, and an oval according to the field to which the display device 1 is applied, for example. The exemplified planar shape of the display device 1 is a rectangle with rounded corners, and long sides LS1 and LS2 are disposed parallel to the second direction DR2. For ease of description, a long side disposed on one side (a left side in a plan view in the drawing) among two facing long sides of the rectangle will be also referred to as a first long side LS1, and a long side disposed on an opposite side (a right side in a plan view in the drawing) will be also referred to as a second long side LS2. In addition, a short side disposed on one side (a lower side in a plan view in the drawing) among two short sides facing each other will be also referred to as a first short side SS1, and a short side disposed on an opposite side (an upper side in a plan view in the drawing) will be also referred to as a second short side SS2. The terms “the first long side LS1,” the second long side LS2,” “the first short side SS1,” and “the second short side SS2” will be used to refer to corresponding sides of not only the display device 1 but also an element included in the display device 1 when the element has a shape and positional relationship similar to those of the display device 1.

The display device 1 includes a display area DA and a non-display area NDA. The display area DA is an area where a screen is displayed, and the non-display area NDA is an area where no screen is displayed. The terms “the display area DA” and “the non-display area NDA” may be used to refer to corresponding areas of not only the display device 1 but also an element included in the display device 1 when the element has a shape and positional relationship similar to those of the display device 1.

A plurality of pixels PX may be disposed in the display area DA. The structure of the pixels PX will be described later.

The non-display area NDA may be disposed around the display area DA. When the display area DA has a quadrangular shape, e.g., rectangular shape, the non-display area NDA may surround four sides of the display area DA. However, embodiments of the specification are not limited thereto. In an embodiment, the non-display area NDA may also be disposed outside only some sides of the display area DA, for example. In some cases, the non-display area NDA may exist inside the display area DA and may be surrounded by the display area DA.

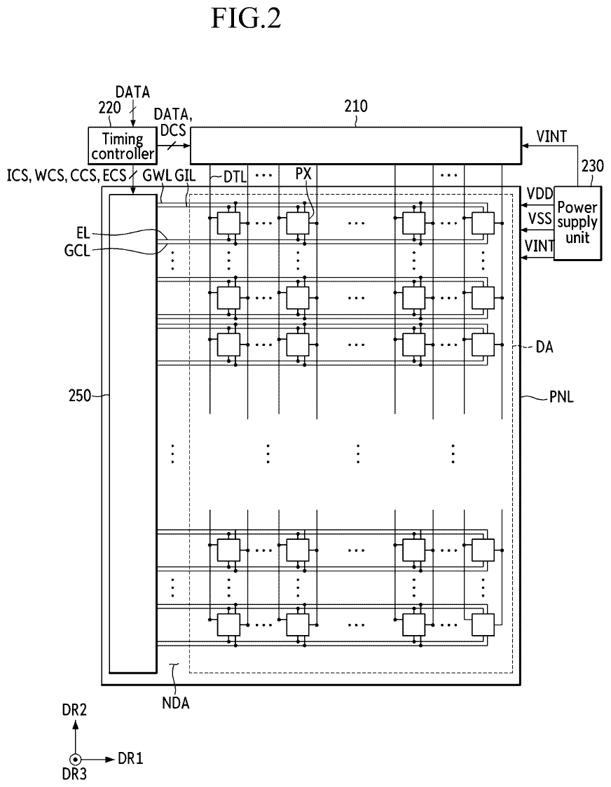

FIG. 2 is a schematic block diagram of an embodiment of the display device 1 according to the specification.

Referring to FIGS. 1A to 2, the display device 1 includes a display panel PNL. The display device 1 may further include a driving unit connected to the display panel PNL.

In the specification, the term “connect” may mean that any one member and another member are connected to each other not only through physical contact but also through another member. In addition, it may be understood that any one part and another part are connected to each other as one integrated member. Further, the connection between any one member and another member may be interpreted to include electrical connection through another member in addition to connection through direct contact.

The display panel PNL provides a display screen. In the exemplified display device 1, a direction in which the display panel PNL provides the display screen is the third direction DR3. The display panel PNL may have a planar shape substantially similar to that of the display device 1. The display area DA of the display device 1 may also be also referred to as the display area DA of the display panel PNL as described above. The display area DA of the display panel PNL includes a plurality of pixels PX arranged in a matrix shape.

In embodiments, the display panel PNL may include an organic light-emitting display panel, a micro light-emitting diode (“LED”) display panel, a nano LED display panel, a quantum dot light-emitting display panel, a liquid crystal display panel, a plasma display panel, a field emission display panel, an electrophoretic display panel, and an electrowetting display panel. A case where an organic light-emitting display panel is applied in an embodiment of the display panel PNL will be described below, but embodiments of the specification are not limited to this case, and other display panels may also be applied as long as the same technical spirit is applicable.

The driving unit drives the display panel PNL. At least some elements of the driving unit drive the pixels PX disposed in the display area DA of the display panel PNL. In some embodiments, the driving unit may be provided in the form of a chip, film and/or circuit board.

The driving unit may include a display scan driver 250, a data driver 210, a timing controller 220, and a power supply unit 230. Although the driving unit is disposed in the non-display area NDA of the display panel PNL, some of the driving unit may also be disposed in the display area DA.

In the display area DA, not only the pixels PX but also a plurality of lines connected from the driving unit are disposed. The lines may include a plurality of display write lines GWL, a plurality of display initialization lines GIL, a plurality of display control lines GCL, a plurality of emission lines EL, and a plurality of data lines DTL.

The data lines DTL may extend in the second direction DR2. The display write lines GWL, the display initialization lines GIL, the display control lines GCL, and the emission lines EL may extend in the first direction DR1.

Each of the pixels PX may be connected to any one of the display write lines GWL, any one of the display initialization lines GIL, any one of the display control lines GCL, and any one of the emission lines EL. Each of the pixels PX may receive a data voltage of a data line DTL according to a display write signal of a display write line GWL, a display initialization signal of a display initialization line GIL, a display control signal of a display control line GCL and an emission signal of an emission line EL and may emit light by supplying a driving current to a light-emitting element according to the data voltage.

The display scan driver 250 may be connected to the display write lines GWL, the display initialization lines GIL, the display control lines GCL, and the emission lines EL. The display scan driver 250 may include a display signal output unit which outputs display write signals transmitted to the display write lines GWL, display initialization signals transmitted to the display initialization lines GIL and display control signals transmitted to the display control lines GCL and an emission signal output unit which outputs emission signals transmitted to the emission lines EL.

The display scan driver 250 may receive a write control signal WCS, an initialization control signal ICS, a scan control signal CCS, and an emission control signal ECS from the timing controller 220. The display signal output unit of the display scan driver 250 may generate display write signals according to the write control signal SCS and output the display write signals to the display write lines GWL. In addition, the display signal output unit of the display scan driver 250 may generate display initialization signals according to the initialization control signal ICS and output the display initialization signals to the display initialization lines GIL. In addition, the display signal output unit of the display scan driver 250 may generate display control signals according to the scan control signal CCS and output the display control signals to the display control lines GCL. Furthermore, the emission signal output unit of the display scan driver 250 may generate display emission signals according to the emission control signal ECS and output the display emission signals to the display emission lines EL.

The data driver 210 converts digital video data DATA into data voltages and outputs the data voltages to the data lines DTL. The data driver 210 may output the data voltages in synchronization with the display write signals. Pixels PX may be selected by the display write signals of the display scan driver 250, and the data voltages may be supplied to the selected pixels PX, respectively.

The timing controller 220 receives the digital video data DATA and timing signals from an external graphics device. In an embodiment, the external graphics device may be, but is not limited to, a graphic card of a computer or a set-top box, for example.

The timing controller 220 may generate the write control signal WCS, the initialization control signal ICS, the scan control signal CCS, and the emission control signal ECS for controlling the operation timing of the display scan driver 250 according to the timing signals. In addition, the timing controller 220 may generate a data control signal DCS for controlling the operation timing of the data driver 210 according to the timing signals.

The timing controller 220 may output the write control signal WCS, the initialization control signal ICS, the scan control signal CCS, and the emission control signal ECS to the display scan driver 250. The timing controller 220 may output the digital video data DATA and the data control signal DCS to the data driver 210.

The power supply unit 230 may generate a plurality of driving voltages and output the driving voltages to the display area DA. The power supply unit 230 may output a first driving voltage VDD, a second driving voltage VSS, and an initialization voltage VINT to the display panel PNL. The first driving voltage VDD may be a high-potential driving voltage, the second driving voltage VSS may be a low-potential driving voltage having a voltage level lower than that of the high-potential driving voltage, and the initialization voltage VINT may be a voltage for initializing a gate electrode of a driving transistor of each pixel PX.

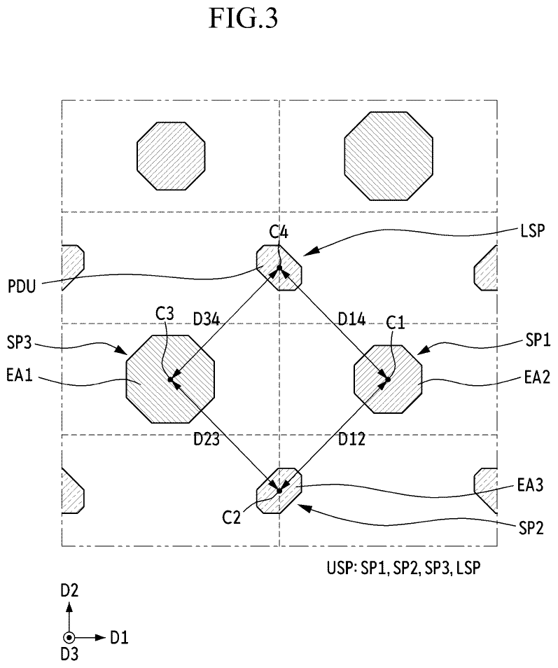

FIG. 3 is a plan view of an embodiment of a display area according to the specification.

Referring to FIG. 3, the display area may include first subpixels SP1, second subpixels SP2, third subpixels SP3, and light sensing pixels LSP. Subpixels SP may be divided into the first subpixels SP1, the second subpixels SP2, and the third subpixels SP3. A first subpixel SP1, a second subpixel SP2, a third subpixel SP3, and a light sensing pixel LSP may be defined as a unit subpixel USP. The unit subpixel USP may be defined as a smallest unit of subpixels that may sense light while displaying white.

In an embodiment, the second subpixel SP2 may be disposed at a position where the light sensing pixel LSP is disposed. A display device in an embodiment may include only the first subpixel SP1, the second subpixel SP2, and the third subpixel SP3. However, the following description assumes that the light sensing pixel LSP is also disposed in the display device.

The first subpixel SP1 may include a second emission area EA2 emitting first light and a first pixel driver for supplying a driving current to a light-emitting element of the second emission area EA2. The first light may be light in a red wavelength band. In an embodiment, a main peak wavelength of the first light may be disposed at about 495 nanometers (nm) to about 570 nm, for example.

The second subpixel SP2 may include a third emission area EA3 emitting second light and a second pixel driver for supplying a driving current to a light-emitting element of the third emission area EA3. The second light may be light in a green wavelength band. In an embodiment, a main peak wavelength of the second light may be disposed at about 370 nm to about 460 nm, for example.

The third subpixel SP3 may include a first emission area EA1 emitting third light and a third pixel driver for supplying a driving current to a light-emitting element of the first emission area EA1. The third light may be light in a blue wavelength band. In an embodiment, a main peak wavelength of the third light may be disposed at about 400 nm to about 495 nm, for example.

The light sensing pixel LSP includes a light sensing unit PDU.

The first emission area EA1, the second emission area EA2, the third emission area EA3, and the light sensing unit PDU may have a polygonal shape including a quadrangle, an octagon, or a rhombus, but embodiments of the specification are not limited thereto. The first emission area EA1, the second emission area EA2, the third emission area EA3, and the light sensing unit PDU may also have a polygonal planar shape other than a quadrangle, an octagon, and a rhombus.

The second emission area EA2 may be disposed in the first direction D1 from the first emission area EA1. The light sensing unit PDU may be disposed in the second direction D2 from the third emission area EA3. The second emission area EA2 and the first emission area EA1 may be disposed in diagonal directions (e.g., directions between the first direction D1 and the second direction D2) from the third emission area EA3. In addition, the second emission area EA2 and the first emission area EA1 may be disposed in diagonal directions (e.g., directions between the first direction D1 and the second direction D2) from the light sensing unit PDU. The diagonal directions may form the same angle with the first direction D1 and the second direction D2, but embodiments of the specification are not limited thereto.

Due to the positions and planar shapes of the second emission area EA2, the third emission area EA3, the first emission area EA1, and the light sensing unit PDU, a distance D12 between a center C1 of the second emission area EA2 and a center C2 of the third emission area EA3 neighboring each other, a distance D23 between the center C2 of the third emission area EA3 and a center C3 of the first emission area EA1 neighboring each other, a distance D14 between the center C1 of the second emission area EA2 and a center C4 of the light sensing unit PDU neighboring each other, and a distance D34 between the center C4 of the light sensing unit PDU and the center C3 of the first emission area EA1 may be substantially the same.

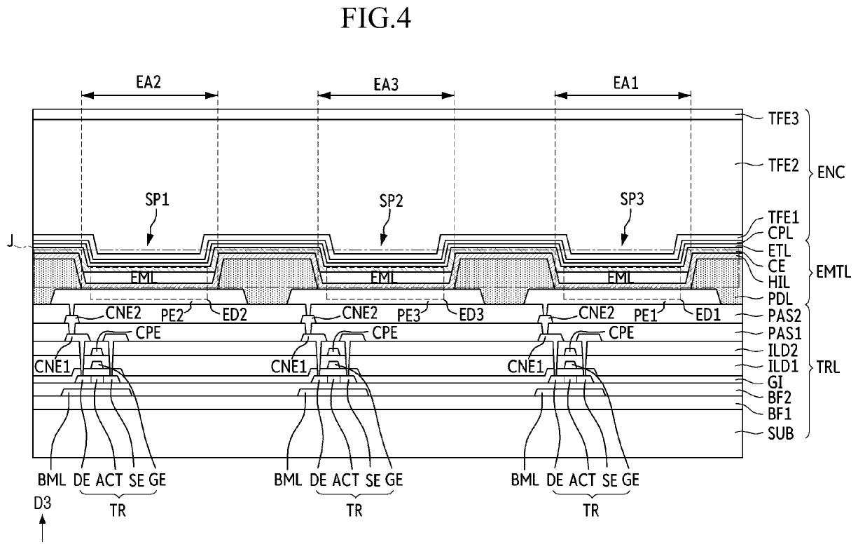

FIG. 4 is a detailed cross-sectional view of a display device including light-emitting elements.

Referring to FIG. 4, the display device may include a substrate SUB, a transistor layer TRL, a light-emitting element layer EMTL, and an encapsulation layer ENC.

The substrate SUB may be a base substrate or a base member. The substrate SUB may be a flexible substrate that may be bent, folded, rolled, etc. In an embodiment, the substrate SUB may include polymer resin such as polyimide (“PI”), for example, but embodiments of the specification are not limited thereto. In another embodiment, the substrate SUB may include a glass material or a metal material. In an alternative embodiment, the substrate SUB may be a silicon substrate on which a semiconductor pattern is formed. In an embodiment, the substrate SUB may be a silicon semiconductor substrate formed through a complementary metal oxide semiconductor (“CMOS”) process, for example. The substrate SUB may include any one of a monocrystalline silicon wafer, a polycrystalline silicon wafer, and/or an amorphous silicon wafer. In addition, the substrate SUB may be a germanium substrate or a silicon-germanium substrate.

The transistor layer TRL may include a first buffer layer BF1, bottom metal layers BML, a second buffer layer BF2, transistors TR, a gate insulating layer GI, a first inter-insulating layer ILD1, capacitor electrodes CPE, a second inter-insulating layer ILD2, first connection electrodes CNE1, a first passivation layer PAS1, second connection electrodes CNE2, and a second passivation layer PAS2.

The first buffer layer BF1 may be disposed on the substrate SUB. The first buffer layer BF1 may include an inorganic layer that may prevent penetration of air or moisture. In an embodiment, the first buffer layer BF1 may include a plurality of inorganic layers stacked alternately, for example.

The bottom metal layers BML may be disposed on the first buffer layer BF1. Each of the bottom metal layers BML may be a single layer or a multilayer including any one or more of molybdenum (Mo), aluminum (Al), chromium (Cr), gold (Au), titanium (Ti), nickel (Ni), neodymium (Nd), copper (Cu), and alloys thereof.

The second buffer layer BF2 may cover the first buffer layer BF1 and the bottom metal layers BML. The second buffer layer BF2 may include an inorganic layer that may prevent penetration of air or moisture. In an embodiment, the second buffer layer BF2 may include a plurality of inorganic layers stacked alternately, for example.

The transistors TR may be disposed on the second buffer layer BF2 and may form respective pixel circuits of a plurality of pixels. In an embodiment, each of the transistors TR may be a driving transistor of a pixel PX circuit, for example. Each of the transistors TR may include a semiconductor layer ACT, a source electrode SE, a drain electrode DE, and a gate electrode GE.

The semiconductor layer ACT may be disposed on the second buffer layer BF2. The semiconductor layer ACT may overlap a bottom metal layer BML and the gate electrode GE in the thickness direction and may be insulated from the gate electrode GE by the gate insulating layer GI. In portions of the semiconductor layer ACT, a material of the semiconductor layer ACT may be made conductive to form the source electrode SE and the drain electrode DE.

The gate electrode GE may be disposed on the gate insulating layer GI. The gate electrode GE may overlap the semiconductor layer ACT with the gate insulating layer GI. The gate insulating layer GI may be disposed between the gate electrode GE and the semiconductor layer ACT.

The gate insulating layer GI may be disposed on the semiconductor layers ACT. In an embodiment, the gate insulating layer GI may cover the semiconductor layers ACT and the second buffer layer BF2 and may insulate the semiconductor layers ACT from the gate electrodes GE, for example. The gate insulating layer GI may include contact holes through which the first connection electrodes CNE1 pass.

The first inter-insulating layer ILD1 may cover the gate electrodes GE and the gate insulating layer GI. The first inter-insulating layer ILD1 may include contact holes through which the first connection electrodes CNE1 pass. The contact holes of the first inter-insulating layer ILD1 may be connected to the contact holes of the gate insulating layer GI and contact holes of the second inter-insulating layer ILD2.

The capacitor electrodes CPE may be disposed on the first inter-insulating layer ILD1. The capacitor electrodes CPE may overlap the gate electrodes GE in the thickness direction. The capacitor electrodes CPE and the gate electrodes GE may form capacitances. In an embodiment, each of the gate electrodes GE may correspond to a first electrode of a capacitor, and each of the capacitor electrodes CPE may correspond to a second electrode of the capacitor, for example.

The second inter-insulating layer ILD2 may cover the capacitor electrodes CPE and the first inter-insulating layer ILD1. The second inter-insulating layer ILD2 may include the contact holes through which the first connection electrodes CNE1 pass. The contact holes of the second inter-insulating layer ILD2 may be connected to the contact holes of the first inter-insulating layer ILD1 and the contact holes of the gate insulating layer GI.

The first connection electrodes CNE1 may be disposed on the second inter-insulating layer ILD2. The first connection electrodes CNE1 may electrically connect the drain electrodes DE of the thin-film transistors TR to the second connection electrodes CNE2. The first connection electrodes CNE1 may be inserted into the contact holes defined in the second inter-insulating layer ILD2, the first inter-insulating layer ILD1, and the gate insulating layer GI to contact the drain electrodes DE of the thin-film transistors TR.

The first passivation layer PAS1 may cover the first connection electrodes CNE1 and the second inter-insulating layer ILD2. The first passivation layer PAS1 may protect the thin-film transistors TR. The first passivation layer PAS1 may include contact holes through which the second connection electrodes CNE2 pass.

The second connection electrodes CNE2 may be disposed on the first passivation layer PAS1. The second connection electrodes CNE2 may electrically connect the first connection electrodes CNE1 to respective pixel electrodes PE1 through PE3 (or first electrodes) of light-emitting elements ED1 through ED3, respectively. The second connection electrodes CNE2 may be inserted into the contact holes defined in the first passivation layer PAS1 to contact the first connection electrodes CNE1.

The second passivation layer PAS2 may cover the second connection electrodes CNE2 and the first passivation layer PAS1. The second passivation layer PAS2 may include contact holes through which the respective pixel electrodes PE1 through PE3 of the light-emitting elements ED1 through ED3 pass.

The light-emitting element layer EMTL may be disposed on the transistors TR. The light-emitting element layer EMTL may include a plurality of light-emitting elements ED1 through ED3 and a bank PDL. The light-emitting elements ED1 through ED3 may include pixel electrodes PE1 through PE3, a light-emitting layer EML, and a common electrode CE.

The display device may include a plurality of emission areas EA1 through EA3 disposed in a display area DA. The emission areas EA1 through EA3 may include a first emission area EA1, a second emission area EA2, and a third emission area EA3 which emit light of different colors. Each of the emission areas EA1 through EA3 may emit blue, red or green light, and the color of light emitted from each of the emission areas EA1 through EA3 may vary according to the type of light-emitting element disposed in the light-emitting element layer EMTL. In an embodiment, the first emission area EA1 may emit blue light, the second emission area EA2 may emit red light, and the third emission area EA3 may emit green light. However, the embodiments of the specification are not limited thereto.

The emission areas EA1 through EA3 may be respectively defined by a plurality of openings defined in the bank PDL of the light-emitting element layer EMTL. In an embodiment, the areas or sizes of the emission areas EA1 through EA3 may be the same. In an embodiment, the first emission area EA1, the second emission area EA2, and the third emission area EA3 may have the same area, for example. However, embodiments of the specification are not limited thereto.

The areas or sizes of the emission areas EA1 through EA3 may be different from each other. The intensity of light emitted from each of the emission areas EA1 through EA3 may vary according to the area of the emission area EA1, EA2 or EA3, and the color of a screen displayed on the display device or an electronic device may be controlled by adjusting the areas of the emission areas EA1 through EA3. In the embodiment of FIG. 4, the first through third emission areas EA1 through EA3 have the same area. However, embodiments of the specification are not limited thereto. The areas of the emission areas EA1 through EA3 may be freely adjusted according to the color of the screen desired by the display device and the electronic device. In addition, the areas of the emission areas EA1 through and EA3 may be related to light efficiency, the life of light-emitting elements ED, etc., and may have a trade-off relationship with reflection from external light. The areas of the emission areas EA1 through EA3 may be adjusted in consideration of the above factors.

In the display device, one first emission area EA1, one second emission area EA2, and one third emission area EA3 next (adjacent) to each other may form one unit pixel. One unit pixel may include the emission areas EA1 through EA3 emitting light of different colors to express a white gray level. However, embodiments of the specification are not limited thereto, and the combination of the emission areas EA1 through EA3 constituting one unit pixel may be variously changed according to the arrangement of the emission areas EA1 through EA3 and the colors of light emitted from the emission areas EA1 through EA3.

The display device may include a plurality of light-emitting elements ED1 through ED3 disposed in the first through third emission areas EA1 through EA3. In an embodiment, the light-emitting element layer EMTL of the display device may include a first light-emitting element ED1 disposed in the first emission area EA1, a second light-emitting element ED2 disposed in the second emission area EA2, and a third light-emitting element ED3 disposed in the third emission area EA3, for example. Each of the first through third light-emitting elements ED1 through ED3 may include a first, second or third pixel electrode PE1, PE2 or PE3, a light-emitting layer EML, and the common electrode CE (or a second electrode).

The emission areas EA1 through EA3 constituting one unit pixel may provide light of various colors through the light-emitting elements ED1 through ED3 which emit light of different colors. In an embodiment, the unit pixel may include a first pixel, a second pixel, a third pixel, and a fourth pixel disposed next (adjacent) to each other, for example. The first pixel may include the first light-emitting element ED1 which emits red light, the second pixel may include the second light-emitting element ED2 which emits blue light, and the third pixel may include the third light-emitting element ED3 which emits green light.

The unit pixel may provide light of various colors by mixing red light from the first light-emitting element ED1 provided in the first pixel, blue light from the second light-emitting element ED2 provided in the second pixel, and green light from the third light-emitting element ED3 provided in the third pixel.

The pixel electrodes PE1 through PE3 may be disposed on the second passivation layer PAS2. In an embodiment, a first pixel electrode PE1 may be disposed to correspond to the first emission area EA1, a second pixel electrode PE2 may be disposed to correspond to the second emission area EA2, and a third pixel electrode PE3 may be disposed to correspond to the third emission area EA3, for example.

Each of the pixel electrodes PE1 through PE3 may be electrically connected to the drain electrode DE of the transistor TR of a corresponding pixel through the first and second connection electrodes CNE1 and CNE2. In an embodiment, the first pixel electrode PE1 may be connected to the drain electrode DE (or the source electrode SE) of a transistor TR provided in the first pixel through first and second connection electrodes CNE1 and CNE2, for example. In addition, the second pixel electrode PE2 may be connected to the drain electrode DE (or the source electrode SE) of a transistor TR provided in the second pixel through other first and second connection electrodes CNE1 and CNE2. In addition, the third pixel electrode PE3 may be connected to the drain electrode DE (or the source electrode SE) of a transistor TR provided in the third pixel through other first and second connection electrodes CNE1 and CNE2.

In an embodiment, each of the pixel electrodes PE1 through PE3 may have a stacked structure in which a material layer having a relatively high work function such as indium tin oxide (“ITO”), indium zinc oxide (“IZO”), zinc oxide (ZnO) or indium oxide (In₂O₃) and a reflective material layer such as silver (Ag), magnesium (Mg), aluminum (Al), platinum (Pt), lead (Pd), palladium (Pd), gold (Au), nickel (Ni), neodymium (Nd), iridium (Ir), chromium (Cr), lithium (Li), calcium (Ca) or any combinations thereof are stacked. The layer having a relatively high work function may be disposed on the reflective material layer so that it is disposed close to the light-emitting layer EML. In an embodiment, each of the pixel electrodes PE1 through PE3 may have, but is not limited to, a multilayer structure of ITO/Mg, ITO/MgF, ITO/Ag, or ITO/Ag/ITO, for example.

The bank PDL (or a pixel defining layer) may be disposed on the first pixel electrode PE1, the second pixel electrode PE2, and the third pixel electrode PE3.

The bank PDL may define the emission areas (the first emission area EA1, the second emission area EA2, and the third emission area EA3) of each pixel. To this end, the bank PDL may be disposed on the second passivation layer PAS2 to expose a portion of each of the first pixel electrode PE1, the second pixel electrode PE2, and the third pixel electrode PE3, for example. In an embodiment, the bank PDL may cover each edge of the first pixel electrode PE1, the second pixel electrode PE2, and the third pixel electrode PE3, for example. The bank PDL may include an organic layer such as acryl resin, epoxy resin, phenolic resin, polyamide resin, or polyimide resin.

The light-emitting layer EML may be disposed on each of the pixel electrodes PE1 through PE3. This will be described in detail with reference to the drawings described below.

The common electrode CE may be disposed on each light-emitting layer EML. In an embodiment, the common electrode CE may be disposed on each light-emitting layer EML to overlap the first pixel electrode PE1, the second pixel electrode PE2, the third pixel electrode PE3, the first emission area EA1, the second emission area EA2, the third emission area EA3, and the bank PDL, for example. The common electrode CE may be a common layer used in common in each of the light-emitting elements ED1 through ED3. In other words, the light-emitting elements ED1 through ED3 of the light-emitting element layer EMTL may share the common electrode CE. In a top emission structure, the common electrode CE may include a transparent conductive material (“TCO”) that may transmit light, such as indium tin oxide (“ITO”) or indium zinc oxide (“IZO”), or may include a semi-transmissive conductive material such as magnesium (Mg), silver (Ag) or an alloy of Mg and Ag. When the common electrode CE includes a semi-transmissive conductive material, light output efficiency may be increased by a microcavity.

A capping layer CPL may be disposed on the common electrode CE. The capping layer CPL may include an inorganic insulating material. In an embodiment, the capping layer CPL may include aluminum oxide, titanium oxide, tantalum oxide, hafnium oxide, zinc oxide, silicon oxide, silicon nitride, and/or silicon oxynitride.

The encapsulation layer ENC may be disposed on the capping layer CPL. The encapsulation layer ENC may cover upper and side surfaces of the light-emitting element layer EMTL and protect the light-emitting element layer EMTL. The encapsulation layer ENC may include at least one inorganic layer and at least one organic layer to encapsulate the light-emitting element layer EMTL. The encapsulation layer ENC may include at least one inorganic layer TFE1 and TFE3 to prevent oxygen or moisture from penetrating into the light-emitting element layer EMTL. In addition, the encapsulation layer ENC may include at least one organic layer to protect the light-emitting element layer EMTL from foreign substances such as dust. In an embodiment, the encapsulation layer ENC may include a first encapsulating inorganic layer TFE1, an encapsulating organic layer TFE2, and a second encapsulating inorganic layer TFE3, for example.

The first encapsulating inorganic layer TFE1 may be disposed on the capping layer CPL, the encapsulating organic layer TFE2 may be disposed on the first encapsulating inorganic layer TFE1, and the second encapsulating inorganic layer TFE3 may be disposed on the encapsulating organic layer TFE2. Each of the first encapsulating inorganic layer TFE1 and the second encapsulating inorganic layer TFE3 may be a multilayer in which one or more inorganic layers selected from a silicon nitride layer, a silicon oxynitride layer, a silicon oxide layer, a titanium oxide layer, and an aluminum oxide layer are alternately stacked. The encapsulating organic layer TFE2 may be an organic layer such as acryl resin, epoxy resin, phenolic resin, polyamide resin, or polyimide resin.

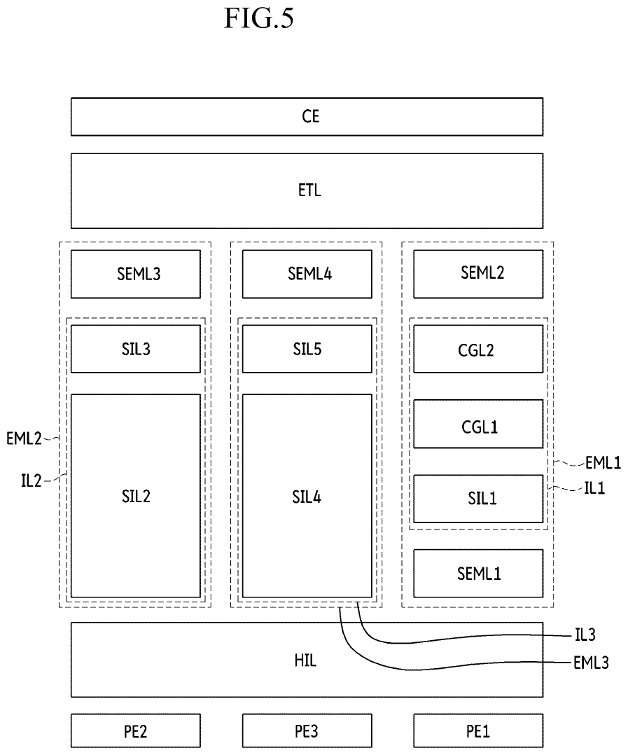

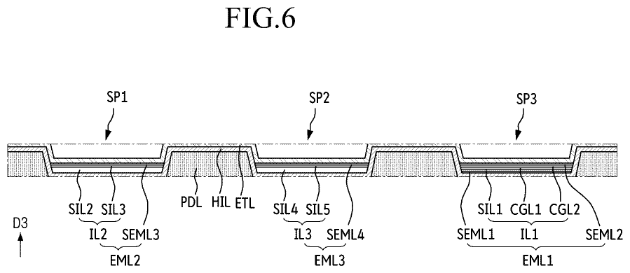

FIG. 5 schematically illustrates light-emitting elements of a display device. FIG. 6 illustrates FIG. 5 in detail.

FIG. 6 is also an enlarged view of portion ‘J’ of FIG. 4.

Referring to FIGS. 5 and 6, a first common layer HIL may be disposed on a first pixel electrode PE1, a second pixel electrode PE2, and a third pixel electrode PE3. The first common layer HIL may include a hole transport layer disposed on the first pixel electrode PE1, the second pixel electrode PE2 and the third pixel electrode PE3 or may include a hole transport layer and a hole injection layer.

In a first light-emitting element, a first light-emitting layer EML1 may be disposed on the first common layer HIL. In a second light-emitting element, a second light-emitting layer EML2 may be disposed on the first common layer HIL. In a third light-emitting element, a third light-emitting layer EML3 may be disposed on the first common layer HIL.

A second common layer ETL may be disposed on the first light-emitting layer EML1, the second light-emitting layer EML2, and the third light-emitting layer EML3. The second common layer ETL may include an electron transport layer and/or an electron injection layer.

In a display device in an embodiment of the specification, the first light-emitting element may include a plurality of sub-light-emitting layers including a first sub-light-emitting layer SEML1 and a second sub-light-emitting layer SEML2, the second light-emitting element may include a single (or one) third sub-light-emitting layer SEML3, and the third light-emitting element may include a single (or one) fourth sub-light-emitting layer SEML4. Light efficiency among first light emitted from the first light-emitting element, second light emitted from the second light-emitting element, and third light emitted from the third light-emitting element may be controlled by the number of light-emitting layers, etc.

In an embodiment, the first light-emitting layer EML1 may include the first sub-light-emitting layer SEML1, the second sub-light-emitting layer SEML2, and a first intermediate layer IL1. The first intermediate layer IL1 may be disposed between the first sub-light-emitting layer SEML1 and the second sub-light-emitting layer SEML2.

The first intermediate layer IL1 may include a first sub-intermediate layer SIL1, a first charge generation layer CGL1, and a second charge generation layer CGL2 stacked sequentially. In an embodiment, the first sub-intermediate layer SIL1 may include an electron transport layer and/or an electron injection layer, for example.

The first light-emitting element including the first charge generation layer CGL1 and the second charge generation layer CGL2 may be a tandem light-emitting element. Since the first light-emitting element has a structure in which a plurality of sub-light-emitting layers are stacked, color purity and luminous efficiency may be improved.

The first charge generation layer CGL1 may be a negative charge generation layer (n-CGL). The second charge generation layer CGL2 may be a positive charge generation layer (p-CGL). Each of the first charge generation layer CGL1 and the second charge generation layer CGL2 may include a host and a dopant. The host may include an organic material.

Negative charges supplied from the first charge generation layer CGL1 may move toward the first sub-light-emitting layer SEML1 and may be combined with positive charges supplied from the first pixel electrode PE1 to generate excitons. The negative charges may be electrons, and the positive charges may be holes. In reality, only the electrons move. However, for ease of description, it is assumed that the holes also move.

In the first sub-light-emitting layer SEML1, electrons generated from the first charge generation layer CGL1 and passing through the first sub-intermediate layer SIL1 and holes generated from the first pixel electrode PE1 and passing through the first common layer HIL may be combined. Therefore, light emission may occur in the first sub-light-emitting layer SEML1 due to the generation of excitons by the above combination.

Positive charge supplied from the second charge generation layer CGL2 may move toward the second sub-light-emitting layer SEML2 and may be combined with negative charges supplied from the common electrode CE to generate excitons.

In the second sub-light-emitting layer SEML2, holes generated from the second charge generation layer CGL2 and electrons generated from the common electrode CE and passing through the second common layer ETL may be combined. Therefore, light emission may occur in the second sub-light-emitting layer SEML2 due to the generation of excitons by the above combination.

In an embodiment, the second light-emitting layer EML2 may include a second intermediate layer IL2 and the third sub-light-emitting layer SEML3. The second intermediate layer IL2 may include a second sub-intermediate layer SIL2 and a third sub-intermediate layer SIL3. The third sub-intermediate layer SIL3 may be disposed between the second sub-intermediate layer SIL2 and the third sub-light-emitting layer SEML3.

Light emission may occur in the third sub-light-emitting layer SEML3. Positive charges supplied from the second pixel electrode PE2 may pass through the first common layer HIL, the second sub-intermediate layer SIL2 and the third sub-intermediate layer SIL3 and then may be combined with negative charges supplied from the common electrode CE. Accordingly, excitons may be generated, and light emission may occur in the third sub-light-emitting layer SEML3.

In an embodiment, the second sub-intermediate layer SIL2 may include a hole transport layer or may include a hole transport layer and a hole injection layer.

The third sub-intermediate layer SIL3 may perform an auxiliary function. In an embodiment, the third sub-intermediate layer SIL3 may function as an electron blocker that blocks electrons moving from the common electrode CE to the third sub-light-emitting layer SEML3 and then passing through the third sub-light-emitting layer SEML3, for example. In an alternative embodiment, the third sub-intermediate layer SIL3 may be a layer for balancing a thickness and/or height with that of the first light-emitting element. In an alternative embodiment, the third sub-intermediate layer SIL3 may perform a function of facilitating the injection of holes moving from the second pixel electrode PE2 toward the third sub-light-emitting layer SEML3.

In an embodiment, the third light-emitting layer EML3 may include a third intermediate layer IL3 and the fourth sub-light-emitting layer SEML4. The third intermediate layer IL3 may include a fourth sub-intermediate layer SIL4 and a fifth sub-intermediate layer SIL5. The fifth sub-intermediate layer SIL5 may be disposed between the fourth sub-intermediate layer SIL4 and the fourth sub-light-emitting layer SEML4.

Light emission may occur in the fourth sub-light-emitting layer SEML4. Positive charges supplied from the third pixel electrode PE3 may pass through the first common layer HIL, the fourth sub-intermediate layer SIL4 and the fifth sub-intermediate layer SIL5 and then may be combined with negative charges supplied from the common electrode CE. Accordingly, excitons may be generated, and light emission may occur in the fourth sub-light-emitting layer SEML4.

In an embodiment, the fourth sub-intermediate layer SIL4 may include a hole transport layer or may include a hole transport layer and a hole injection layer.

The fifth sub-intermediate layer SIL5 may perform an auxiliary function. In an embodiment, the fifth sub-intermediate layer SIL5 may function as an electron blocker that blocks electrons moving from the common electrode CE to the fourth sub-light-emitting layer SEML4 and then passing through the fourth sub-light-emitting layer SEML4, for example. In an alternative embodiment, the fifth sub-intermediate layer SIL5 may be a layer for balancing a thickness and/or height with that of the first light-emitting element. In an alternative embodiment, the fifth sub-intermediate layer SIL5 may perform a function of facilitating the injection of holes moving from the third pixel electrode PE3 toward the fourth sub-light-emitting layer SEML4.

Referring to FIG. 6, a third subpixel SP3 may include the first light-emitting element, a first subpixel SP1 may include the second light-emitting element, and a second subpixel SP2 may include the third light-emitting element. As described above, the first subpixel SP1 may emit red light, the second subpixel SP2 may emit green light, and the third subpixel SP3 may emit blue light, but embodiments of the specification are not limited thereto. In consideration of the efficiency and/or life of the light-emitting elements, the area of the first emission area EA1 provided in the third subpixel SP3 that emits blue light may be larger than the areas of the second emission area EA2 and third emission area EA3.

The first common layer HIL may cover the bank PDL, and each of the first light-emitting layer EML1, the second light-emitting layer EML2 and the third light-emitting layer EML3 may be disposed in a space between a plurality of banks PDL spaced apart from each other.

The first light-emitting layer EML1 may include the first sub-light-emitting layer SEML1, the second sub-light-emitting layer SEML2, and the first sub-intermediate layer SIL1, the first charge generation layer CGL1 and the second charge generation layer CGL2 sequentially disposed between the first sub-light-emitting layer SEML1 and the second sub-light-emitting layer SEML2.

The second light-emitting layer EML2 may include the second sub-intermediate layer SIL2, the third sub-intermediate layer SIL3, and the third sub-light-emitting layer SEML3 disposed between the first common layer HIL and the second common layer ETL.

The third light-emitting layer EML3 may include the fourth sub-intermediate layer SIL4, the fifth sub-intermediate layer SIL5, and the fourth sub-light-emitting layer SEML4 disposed between the first common layer HIL and the second common layer ETL.

As described above, when each of the first light-emitting layer EML1, the second light-emitting layer EML2, and the third light-emitting layer EML3 is disposed to fit perfectly between the first common layer HIL and the second common layer ETL without any error or deviation due to a deposition process, color efficiency may be improved.

When there is no error due to the deposition process, both one end and an opposite end of each of the elements included in the first light-emitting layer EML1 may be disposed between a plurality of banks PDL. In addition, both one end and an opposite end of each of the elements included in the second light-emitting layer EML2 may be disposed between a plurality of banks PDL. In addition, both one end and an opposite end of each of the elements included in the third light-emitting layer EML3 may be disposed between a plurality of banks PDL. This arrangement is ideal, and a display device including light-emitting elements arranged ideally may provide light efficiency in a wavelength band desired by an implementer.

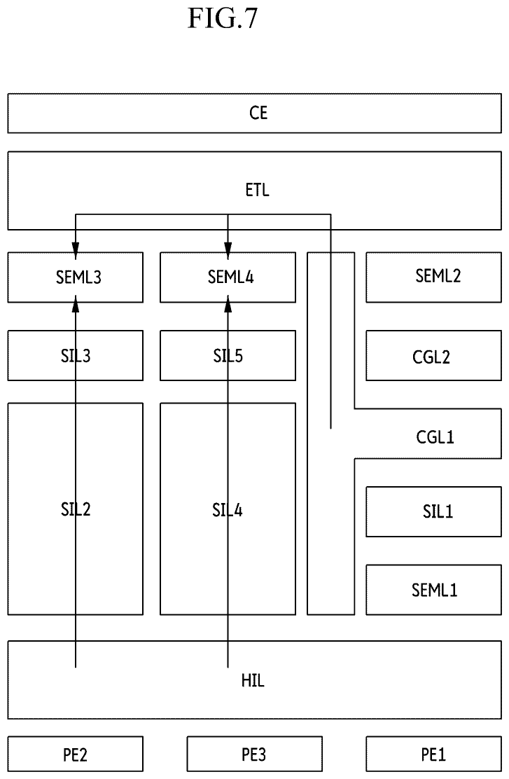

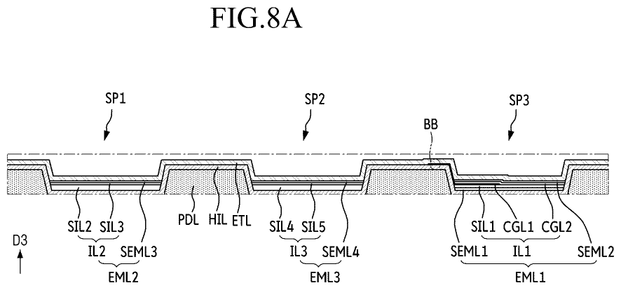

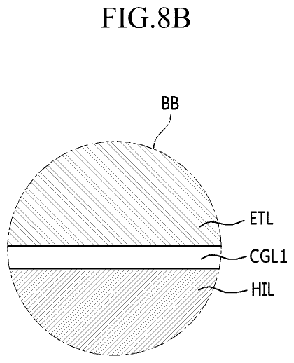

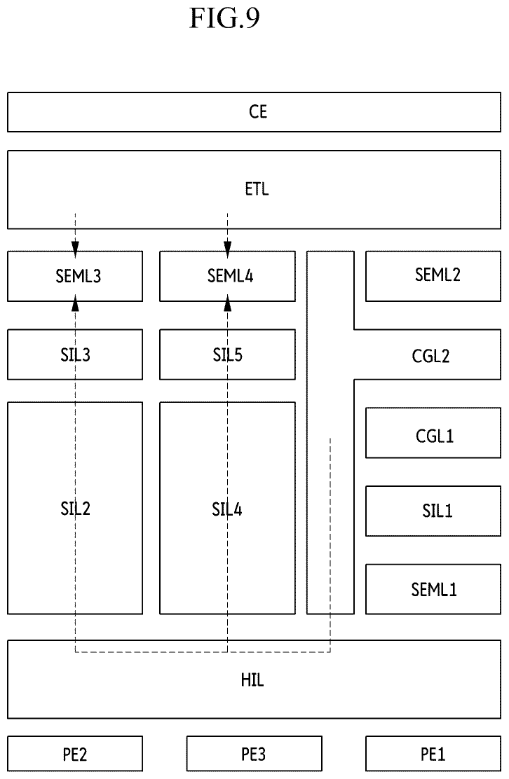

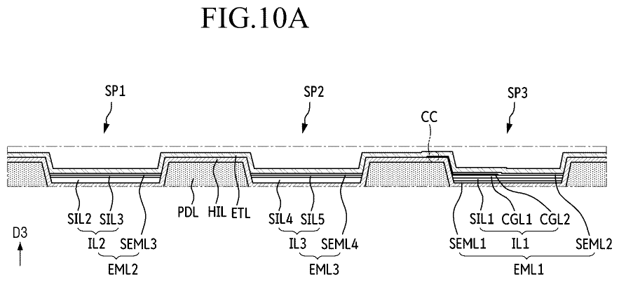

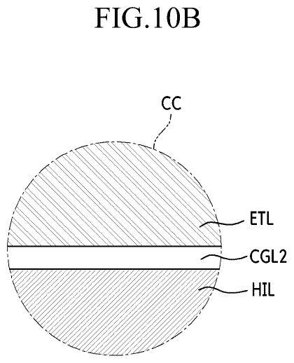

FIG. 7 schematically illustrates current leakage due to a deposition position deviation of the first charge generation layer CGL1. FIG. 8A illustrates FIG. 7 in detail, and FIG. 8B is an enlarged view of portion BB of FIG. 8A. FIG. 9 schematically illustrates current leakage due to a deposition position deviation of the second charge generation layer CGL2. FIG. 10A illustrates FIG. 9 in detail, and FIG. 10B is an enlarged view of portion CC of FIG. 10A.

Referring to FIGS. 7 to 8B, when a process of depositing the first charge generation layer CGL1 is performed, an error and/or a deviation due to the deposition process may occur. This may be caused by an error in terms of fine units in a mask process.

In an embodiment, one end of the first charge generation layer CGL1 may be disposed on a bank PDL, and an opposite end may be disposed between a plurality of banks PDL, for example. Assuming that the elements of the first light-emitting layer EML1 excluding the first charge generation layer CGL1 are deposited without an error due to a deposition process, the third subpixel SP3 may include both an area in a plan view where the first charge generation layer CGL1 is disposed between a plurality of banks PDL and an area in the plan view where the first charge generation layer CGL1 is not disposed.

As described above, when there is no deviation due to a deposition position, the first charge generation layer CGL1 supplies electrons in a direction in which the first sub-light-emitting layer SEML1 is disposed. However, when there is a deviation as in the above case, electrons may move in a direction in which the second common layer ETL including the electron transport layer, etc. is disposed. Since the second common layer ETL performs a function of supplying electrons from the common electrode CE to a light-emitting layer, it may supply the negative charges generated from the first charge generation layer CGL1 when an error in the deposition position of the first charge generation layer CGL1 occurs.

Referring to the arrows, the negative charges generated from the first charge generation layer CGL1 may not move toward the first sub-light-emitting layer SEML1 which is the original destination but may move toward the third sub-light-emitting layer SEML3 and/or the fourth sub-light-emitting layer SEML4. Compared with a case where no error and/or deviation occurs due to a deposition process, leakage of the negative charges may occur. In this case, the light efficiency of the first light-emitting element may decrease.

Referring to FIGS. 9 to 10B, when a process of depositing the second charge generation layer CGL2 is performed, an error and/or a deviation due to the deposition process may occur. This may be caused by an error in terms of fine units in a mask process.

In an embodiment, one end of the second charge generation layer CGL2 may be disposed on a bank PDL, and an opposite end may be disposed between a plurality of banks PDL, for example. Assuming that the elements of the first light-emitting layer EML1 excluding the second charge generation layer CGL2 are deposited without an error due to a deposition process, the third subpixel SP3 may include both an area in a plan view where the second charge generation layer CGL2 is disposed between a plurality of banks PDL and an area in the plan view where the second charge generation layer CGL2 is not disposed.

As described above, when there is no deviation due to a deposition position, the second charge generation layer CGL2 supplies holes in a direction in which the second sub-light-emitting layer SEML2 is disposed. However, when there is a deviation as in the above case, holes may move in a direction in which the first common layer HIL including the hole transport layer, etc. is disposed. Since the first common layer HIL performs a function of supplying holes from a pixel electrode to a light-emitting layer, it may supply the positive charges generated from the second charge generation layer CGL2 when an error in the deposition position of the second charge generation layer CGL2 occurs.

Referring to the arrows, the positive charges generated from the second charge generation layer CGL2 may not move toward the second sub-light-emitting layer SEML2 which is the original destination but may move toward the third sub-light-emitting layer SEML3 and/or the fourth sub-light-emitting layer SEML4. Compared with a case where no error and/or deviation occurs due to a deposition process, leakage of the positive charges may occur. In this case, the light efficiency of the first light-emitting element may decrease.

Referring to FIGS. 7 through 10B, when an error occurs in the process of depositing the first charge generation layer CGL1 and/or the second charge generation layer CGL2 as described above, an electric current that should flow to the first light-emitting element may flow toward the second light-emitting element and the third light-emitting element. This is referred to as lateral leakage.

When a light-emitting element including a tandem structure is placed, a charge generation layer may contribute to the emission of light having a wavelength band other than a wavelength band intended by an implementer. This may reduce the efficiency of the display device in terms of light efficiency and/or color purity and power consumption.

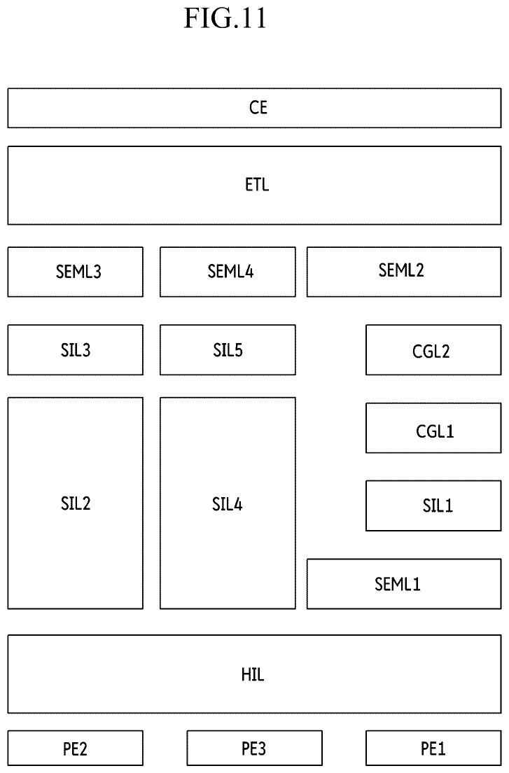

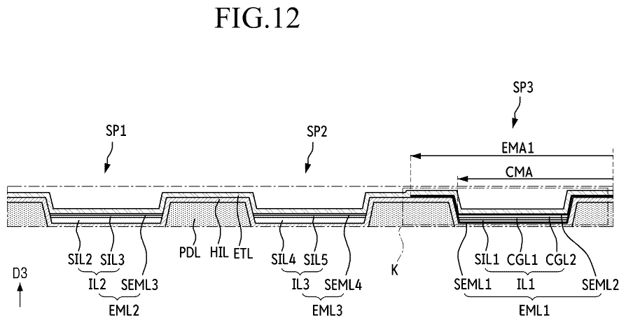

FIG. 11 schematically illustrates an embodiment of light-emitting elements of a display device according to the specification. FIG. 12 illustrates FIG. 11 in detail.

Referring to FIGS. 11 and 12, the display device in the embodiment of the specification provides a technical solution to the above-described problem. In an embodiment, a first sub-light-emitting layer SEML1 and a second sub-light-emitting layer SEML2 in the display device may be formed to have a larger area than a first intermediate layer IL1, for example.

In an embodiment, the first sub-light-emitting layer SEML1 and the second sub-light-emitting layer SEML2 may have a larger area than a first charge generation layer CGL1. The first sub-light-emitting layer SEML1 and the second sub-light-emitting layer SEML2 may have a larger area than a second charge generation layer CGL2. The first sub-light-emitting layer SEML1 and the second sub-light-emitting layer SEML2 may have a larger area than a first sub-intermediate layer SIL1.

The entirety of the first charge generation layer CGL1 may overlap the first sub-light-emitting layer SEML1 and the second sub-light-emitting layer SEML2. The entirety of the second charge generation layer CGL2 may overlap the first sub-light-emitting layer SEML1 and the second sub-light-emitting layer SEML2. The entirety of the first sub-intermediate layer SIL1 may overlap the first sub-light-emitting layer SEML1 and the second sub-light-emitting layer SEML2.

In an embodiment, the second sub-light-emitting layer SEML2 may include a first area EMA1 overlapping the first sub-light-emitting layer SEML1. In addition, a charge generation area CMA may be defined in a first light-emitting element. The charge generation area CMA is an area overlapping a charge generation layer. In the display device in the embodiment, the area of the first area EMA1 may be larger than the area of the charge generation area CMA. In an embodiment, the entirety of the charge generation area CMA may overlap the first area EMA1, for example. At least a portion of the first area EMA1 may overlap the charge generation area CMA.

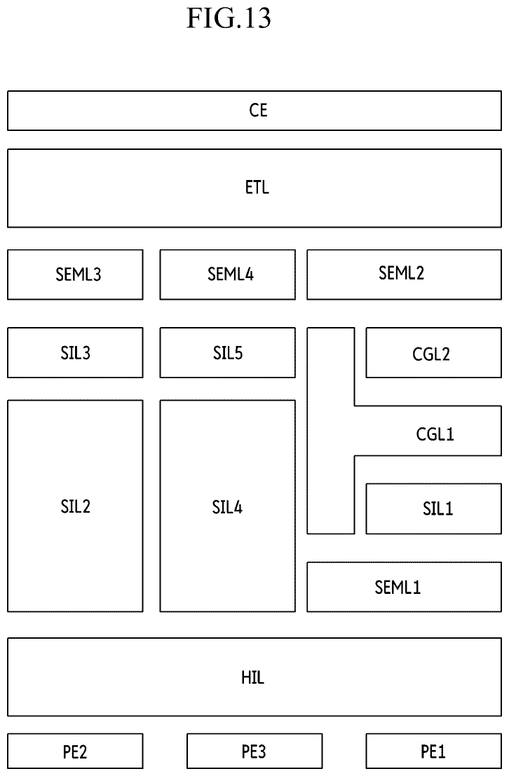

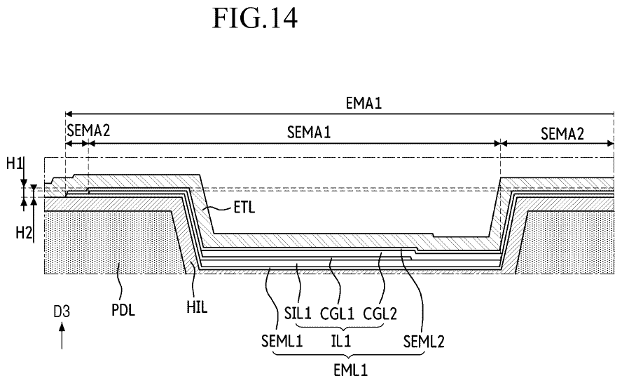

FIG. 13 schematically illustrates a case where an error occurs in an embodiment of the deposition position of the first charge generation layer CGL1 in the display device according to the specification. FIG. 14 illustrates FIG. 13 in detail.

FIG. 14 is also an enlarged view of portion ‘K’ of FIG. 12.

Referring to FIGS. 13 and 14, when an error occurs in a process of depositing the first charge generation layer CGL1, one end of the first charge generation layer CGL1 may be disposed on a bank PDL, and an opposite end may be disposed between a plurality of banks PDL. The end of the first charge generation layer CGL1 disposed on the bank PDL may overlap a portion of a first common layer HIL disposed on the bank PDL.

The second sub-light-emitting layer SEML2 may include a first area EMA1 overlapping the first sub-light-emitting layer SEML1. In an embodiment, the first area EMA1 may include a first sub-area SEMA1 overlapping the charge generation layer. In addition, the first area EMA1 may include a second sub-area SEMA2 next (adjacent) to the first sub-area SEMA1.

When an error occurs in the process of depositing the first charge generation layer CGL1, the second charge generation layer CGL2 and the second sub-light-emitting layer SEML2 may be disposed on the first charge generation layer CGL1.

The second sub-light-emitting layer SEML2 has a larger area than the first charge generation layer CGL1. Therefore, even when the deposition position of the first charge generation layer CGL1 changes due to a process error, there is a relatively high probability that the second sub-light-emitting layer SEML2, not a second common layer ETL, will be disposed on a portion of the first charge generation layer CGL1 disposed on the bank PDL.

Referring to the above-described process in which the lateral leakage of an electric current occurs, the probability that a leakage current will be generated via the second common layer ETL may be reduced by the second sub-light-emitting layer SEML2 disposed on a portion of the first charge generation layer CGL1 on the bank PDL.

In the display device in the embodiment of the specification, the areas of the first sub-light-emitting layer SEML1 and the second sub-light-emitting layer SEML2 may be larger than the areas of the first charge generation layer CGL1 and the second charge generation layer CGL2. Accordingly, the areas of the first charge generation layer CGL1 and the second charge generation layer CGL2 which directly contact the first common layer HIL and the second common layer ETL may be reduced. Here, “directly contact” refers to a state in which no other element is disposed between a predetermined element and another predetermined element. By having such a structure, the display device may normalize luminous efficiency in a tandem structure. In addition, since the light efficiency of the display device is improved, the display device may be driven with relatively low power.

In the second sub-area SEMA2, the first sub-light-emitting layer SEML1 and the second sub-light-emitting layer SEML2 may be formed to directly contact each other. In the first sub-area SEMA1, the first sub-light-emitting layer SEML1 and the first charge generation layer CGL1 may be formed to directly contact each other on the bank PDL. In addition, the second sub-light-emitting layer SEML2 and the second charge generation layer CGL2 may be formed to directly contact each other. In the first sub-area SEMA1, the second sub-light-emitting layer SEML2 may contact the second charge generation layer CGL2 between a plurality of banks PDL.

Referring to an area above the bank PDL in terms of thickness, a distance H1 from a lower surface of the first sub-light-emitting layer SEML1 to an upper surface of the second sub-light-emitting layer SEML2 in the first sub-area SEMA1 may be defined. In addition, referring to the area above the bank PDL, a distance H2 from the lower surface of the first sub-light-emitting layer SEML1 to the upper surface of the second sub-light-emitting layer SEML2 in the second sub-area SEMA2 may be defined. When an error occurs, the distance H1 may be greater than the distance H2 due to the first charge generation layer CGL1.

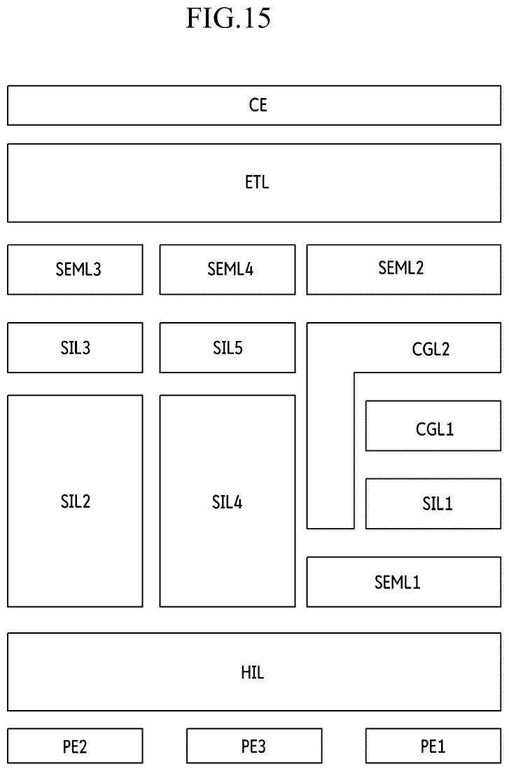

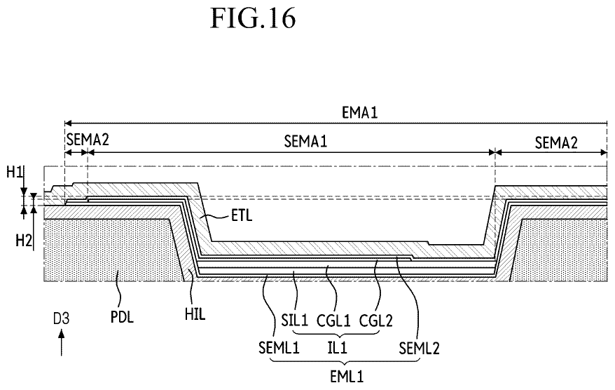

FIG. 15 schematically illustrates a case where an error occurs in an embodiment of the deposition position of the second charge generation layer CGL2 in the display device according to the specification. FIG. 16 illustrates FIG. 15 in detail.

FIG. 16 is also an enlarged view of portion ‘K’ of FIG. 12.

Referring to FIGS. 15 and 16, when an error occurs in a process of depositing the second charge generation layer CGL2, one end of the second charge generation layer CGL2 may be disposed on a bank PDL, and an opposite end may be disposed between a plurality of banks PDL. The end of the second charge generation layer CGL2 disposed on the bank PDL may overlap a portion of the first common layer HIL disposed on the bank PDL.

The second sub-light-emitting layer SEML2 may include a first area EMA1 overlapping the first sub-light-emitting layer SEML1. In an embodiment, the first area EMA1 may include a first sub-area SEMA1 overlapping the charge generation layer. In addition, the first area EMA1 may include a second sub-area SEMA2 next (adjacent) to the first sub-area SEMA1.

When an error occurs in the process of depositing the second charge generation layer CGL2, the first charge generation layer CGL1 and the second sub-light-emitting layer SEML2 may be disposed on the second charge generation layer CGL2.

The second sub-light-emitting layer SEML2 has a larger area than the second charge generation layer CGL2. Therefore, even when the deposition position of the second charge generation layer CGL2 changes due to a process error, there is a relatively high probability that the second sub-light-emitting layer SEML2, not the first common layer HIL, will be disposed on a portion of the second charge generation layer CGL2 disposed on the bank PDL.

Referring to the above-described process in which the lateral leakage of an electric current occurs, the probability that a leakage current will be generated via the first common layer HIL may be reduced by the first sub-light-emitting layer SEML1 disposed below a portion of the second charge generation layer CGL2 on the bank PDL.

In the display device in the embodiment of the specification, the areas of the first sub-light-emitting layer SEML1 and the second sub-light-emitting layer SEML2 may be larger than the areas of the second charge generation layer CGL2 and the first charge generation layer CGL1. Accordingly, the areas of the second charge generation layer CGL2 and the first charge generation layer CGL1 which directly contact the second common layer ETL and the first common layer HIL may be reduced. Here, “directly contact” refers to a state in which no other element is disposed between a predetermined element and another predetermined element. By having such a structure, the display device may normalize luminous efficiency in a tandem structure. In addition, since the light efficiency of the display device is improved, the display device may be driven with relatively low power.

In the second sub-area SEMA2, the first sub-light-emitting layer SEML1 and the second sub-light-emitting layer SEML2 may be formed to directly contact each other. In the first sub-area SEMA1, the first sub-light-emitting layer SEML1 and the second charge generation layer CGL2 may be formed to directly contact each other on the bank PDL. In addition, the second sub-light-emitting layer SEML2 and the first charge generation layer CGL1 may be formed to directly contact each other. In the first sub-area SEMA1, the second sub-light-emitting layer SEML2 may contact the first charge generation layer CGL1 between a plurality of banks PDL.

Referring to an area above the bank PDL in terms of thickness, a distance H1 from the lower surface of the first sub-light-emitting layer SEML1 to the upper surface of the second sub-light-emitting layer SEML2 in the first sub-area SEMA1 may be defined. In addition, referring to the area above the bank PDL, a distance H2 from the lower surface of the first sub-light-emitting layer SEML1 to the upper surface of the second sub-light-emitting layer SEML2 in the second sub-area SEMA2 may be defined. When an error occurs, the distance H1 may be greater than the distance H2 due to the second charge generation layer CGL2.

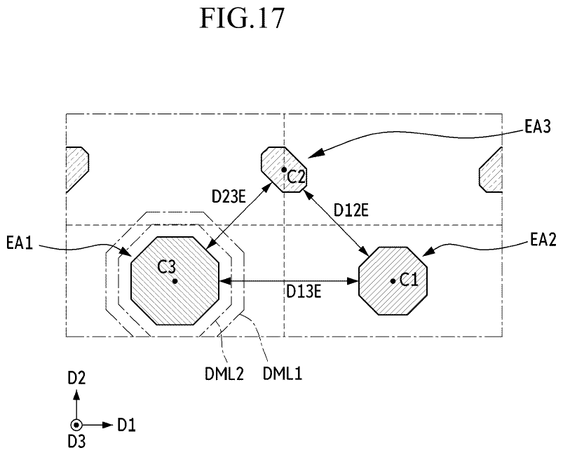

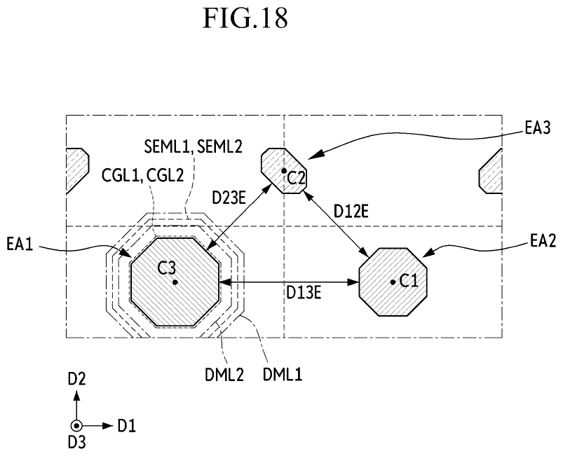

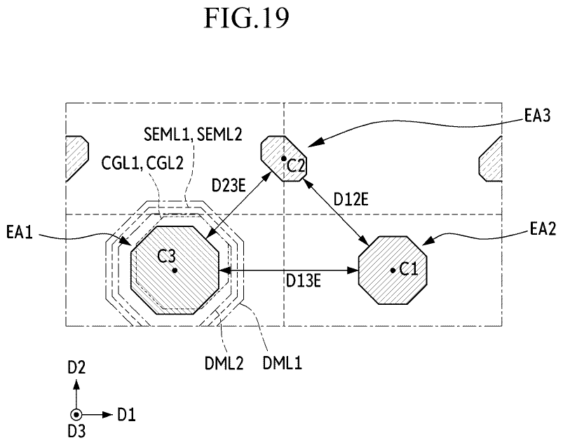

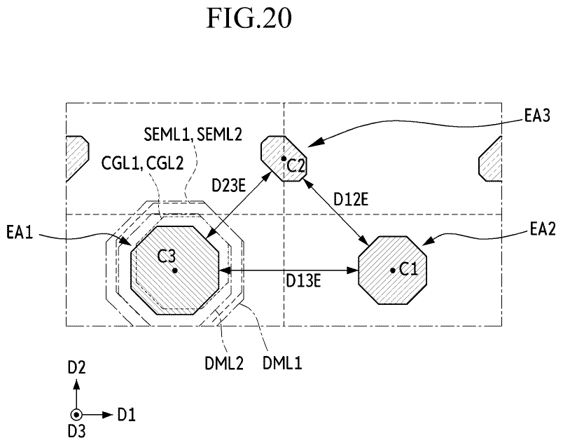

FIG. 17 is a plan view illustrating a deposition margin applied to an embodiment of a display device according to the specification. FIG. 18 is a plan view illustrating a case where no error occurs in a deposition position in the display device in the embodiment of the specification. FIG. 19 is a plan view illustrating a case where an error occurs in an embodiment of the deposition position of a charge generation layer in the display device according to the specification. FIG. 20 is a plan view illustrating a case where an error occurs in an embodiment of the deposition position of a charge generation layer and the deposition position of a light-emitting layer in the display device according to the specification.

Referring to FIG. 17, a first subpixel SP1 may include a second emission area EA2, a second subpixel SP2 may include a third emission area EA3, and a third subpixel SP3 may include a first emission area EA1. The area of the first emission area EA1 may be larger than the area of the second emission area EA2 and the area of the third emission area EA3. In an embodiment, an edge line defined by edges of each of the first emission area EA1, the second emission area EA2, and the third emission area EA3 may be provided.

In an embodiment, a distance D23E between an edge of the third emission area EA3 and an edge of the first emission area EA1 may be smaller than a distance D13E between an edge of the first emission area EA1 and an edge of the second emission area EA2. Therefore, when a maximum value of a deposition margin is preset in consideration of the distance D23E between the edge of the third emission area EA3 and the edge of the first emission area EA1, even when a deposition error of a charge generation layer CGL1 or CGL2 and/or a sub-light-emitting layer SEML1 or SEML2 occurs, the distance D13E between the edge of the first emission area EA1 and the edge of the second emission area EA2 may not be substantially affected by the error due to the deposition process. In the display device in the embodiment, since a first light-emitting element includes the charge generation layers CGL1 and CGL2, it is sufficient to compare only the distance D13E between the edge of the first emission area EA1 and the edge of the second emission area EA2 and the distance D23E between the edge of the third emission area EA3 and the edge of the first emission area EA1.

The charge generation layers CGL1 and CGL2 may be deposited with a second margin line DML2, and the sub-light-emitting layers SEML1 and SEML2 may be deposited with a first margin line DML1.

Referring to FIG. 18, a first sub-light-emitting layer SEML1 and a second sub-light-emitting layer SEML2 may be larger in size than both a first charge generation layer CGL1 and a second charge generation layer CGL2. When no error occurs in a deposition process, the probability that light efficiency will be reduced by current leakage may be relatively low.

In an embodiment, the second margin line DML2 may be disposed closer to a center C3 of the first emission area EA1 than a line defined by the edges of the first sub-light-emitting layer SEML1 and the second sub-light-emitting layer SEML2.

Referring to FIG. 19, even when a maximum error occurs in the deposition process of the first charge generation layer CGL1 and/or the second charge generation layer CGL2, since the areas of the first sub-light-emitting layer SEML1 and the second sub-light-emitting layer SEML2 are already larger than the areas of the first charge generation layer CGL1 and the second charge generation layer CGL2 and since the second margin line DML2 is closer to the center C3 of the first emission area EA1 than the edge line of the sub-light-emitting layer SEML1 and SEML2, the entirety of the charge generation layers CGL1 and CGL2 may overlap the sub-light-emitting layers SEML1 and SEML2.

Even when the sub-light-emitting layers SEML1 and SEML2 are normally deposited, the second margin line DML2 may be closer to the center C3 of the first emission area EA1 than the line defined by the edges of the sub-light-emitting layers SEML1 and SEML2. Therefore, the probability that the charge generation layer CGL1 or CGL2 will directly contact a common layer is low, and the light efficiency of the display device may be improved.

Referring to FIG. 20, when a maximum error occurs in the deposition process of both the charge generation layers CGL1 and CGL2 and the sub-light-emitting layers SEML1 and SEML2, since the areas of the first sub-light-emitting layer SEML1 and the second sub-light-emitting layer SEML2 are already larger than the areas of the first charge generation layer CGL1 and the second charge generation layer CGL2, the probability that the charge generation layer CGL1 or CGL2 will directly contact a common layer may be relatively low. This is substantially similar to the case where no error occurs in the deposition process.

The display device in the embodiment of the specification may be applied to various electronic devices. An electronic device in an embodiment includes the above-described display device and may further include modules or devices having other additional functions, in addition to the display device.

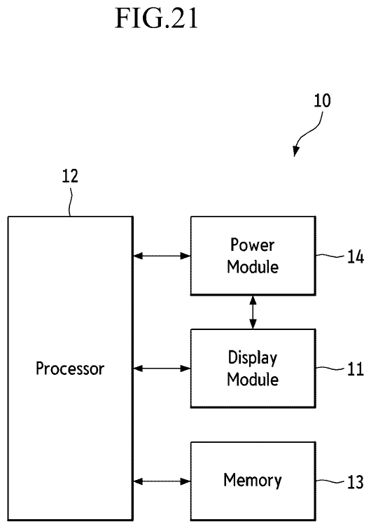

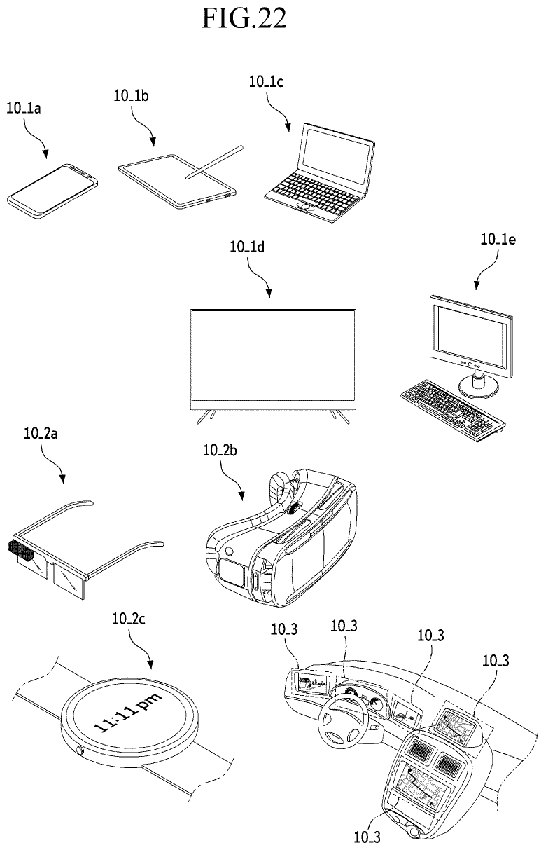

FIG. 21 is a block diagram of an embodiment of an electronic device according to the specification. FIG. 22 is a schematic diagram of embodiments of electronic devices according to the specification.

Referring to FIG. 21, an electronic device 10 in an embodiment may include a display module 11, a processor 12, a memory 13, and a power module 14.

The processor 12 may include at least one of a central processing unit (“CPU”), an application processor (“AP”), a graphic processing unit (“GPU”), a communication processor (“CP”), an image signal processor (“ISP”), and a controller.

The memory 13 may store data information desired for the operation of the processor 12 or the display module 11. When the processor 12 executes an application stored in the memory 13, an image data signal (also referred to as image signal) and/or an input control signal may be transmitted to the display module 11, and the display module 11 may process the received signal and output image information through a display screen.

The power module 14 may include a power supply module such as a power adapter or a battery device. The power module 14 may include a power conversion module. The power conversion module may generate the power desired for the operation of the electronic device 10 by converting power supplied by the power supply module.

At least one of the elements of the electronic device 10 described above may be included in the display device according to the above-described embodiments. In addition, some of individual modules functionally included in one module may be included in the display device, and other modules may be provided separately from the display device. In an embodiment, the display device may include the display module 11, and the processor 12, the memory 13 and the power module 14 may be provided not in the display device but as other devices within the electronic device, for example.

Referring to FIG. 22, various electronic devices to which a display device in embodiments of the specification is applied may include image display electronic devices such as a smartphone 10_1a, a tablet PC 10_1b, a laptop 10_1c, a television 10_1d, and a desk monitor 10_1e. In addition, the various electronic devices to which the display device in the embodiments of the specification is applied may include wearable electronic devices including display modules, such as smart glasses 10_2a, a head mounted display 10_2b and a smart watch 10_2c, and vehicle electronic devices 10_3 including display modules, such as a center information display (“CID”) and a room mirror display placed on an instrument panel, center fascia and dashboard of a vehicle.

Although embodiments of the disclosure have been described above with reference to the accompanying drawings, it will be understood by those having ordinary skill in the technical field to which the disclosure belongs that the disclosure may be practiced in other predetermined forms without altering the technical idea or essential features of the disclosure. It should therefore be understood that the embodiments described above are exemplary in all respects and are not intended to be limiting.

What is claimed is:

1. A display device comprising:
a substrate;
a first electrode disposed on the substrate;
a second electrode disposed on the first electrode; and
a first light-emitting layer disposed between the first electrode and the second electrode, the first light-emitting layer comprising:
a first sub-light-emitting layer;
a charge generation layer; and
a second sub-light-emitting layer,
wherein an area of the first sub-light-emitting layer is larger than an area of the charge generation layer.

2. The display device of claim 1, wherein an area of the second sub-light-emitting layer is larger than the area of the charge generation layer.

3. The display device of claim 1, further comprising:
a first common layer disposed between the first electrode and the first light-emitting layer; and
a second common layer disposed between the first light-emitting layer and the second electrode.

4. The display device of claim 3, comprising:
a first emission area, a second emission area and a third emission area spaced apart from each other;
a second light-emitting layer disposed in the second emission area; and
a third light-emitting layer disposed in the third emission area,
wherein the first light-emitting layer is disposed in the first emission area.

5. The display device of claim 4, wherein an area of the first emission area is larger than an area of the second emission area and an area of the third emission area.

6. The display device of claim 4, wherein each of the second light-emitting layer and the third light-emitting layer is disposed between the first common layer and the second common layer, the second light-emitting layer comprises a second intermediate layer and a third sub-light-emitting layer, and the third light-emitting layer comprises a third intermediate layer and a fourth sub-light-emitting layer.

7. The display device of claim 6, wherein the second intermediate layer comprises a second sub-intermediate layer and a third sub-intermediate layer, and the third intermediate layer comprises a fourth sub-intermediate layer and a fifth sub-intermediate layer.

8. The display device of claim 4, wherein the first light-emitting layer comprises a first intermediate layer comprising the charge generation layer and a first sub-intermediate layer.

9. The display device of claim 8, wherein the area of the first sub-light-emitting layer and an area of the second sub-light-emitting layer are larger than an area of the first sub-intermediate layer.

10. The display device of claim 1, wherein the charge generation layer comprises a first charge generation layer and a second charge generation layer disposed between the first charge generation layer and the second sub-light-emitting layer.

11. The display device of claim 4, wherein the second sub-light-emitting layer comprises a first area overlapping the first sub-light-emitting layer, and the first area comprises a first sub-area overlapping the charge generation layer.

12. The display device of claim 11, wherein the first area further comprises a second sub-area next to the first sub-area, and a distance from a lower surface of the first sub-light-emitting layer to an upper surface of the second sub-light-emitting layer is greater in the first sub-area than in the second sub-area.

13. An electronic device comprising:
a processor which provides an image signal;
a display module which receives the image signal from the processor and displays an image, the display module comprising:
a substrate in which a first emission area, a second emission area and a third emission area spaced apart from each other are defined;
a plurality of first electrodes disposed on the substrate;
a first light-emitting layer disposed on a first electrode overlapping the first emission area among the plurality of first electrodes, the first light-emitting layer comprising:
a first sub-light-emitting layer;
a charge generation layer; and
a second sub-light-emitting layer;
a second light-emitting layer disposed on a first electrode overlapping the second emission area among the plurality of first electrodes, the second light-emitting layer comprising a single light-emitting layer;
a third light-emitting layer disposed on a first electrode overlapping the third emission area among the plurality of first electrodes, the third light-emitting layer comprising a single light-emitting layer; and
a second electrode disposed on the first light-emitting layer, the second light-emitting layer and the third light-emitting layer; and
a power module which supplies power to the display module,
wherein the first light-emitting layer comprises a first sub-light-emitting layer, a charge generation layer and a second sub-light-emitting layer, and each of the second light-emitting layer and the third light-emitting layer comprises a single light-emitting layer.

14. The electronic device of claim 13, wherein the second sub-light-emitting layer comprises a first area overlapping the first sub-light-emitting layer, and the first area comprises a first sub-area overlapping the charge generation layer.

15. The electronic device of claim 14, wherein the first area further comprises a second sub-area next to the first sub-area, and a distance from a lower surface of the first sub-light-emitting layer to an upper surface of the second sub-light-emitting layer is greater in the first sub-area than in the second sub-area.

16. The electronic device of claim 13, wherein an area of the first sub-light-emitting layer is larger than an area of the charge generation layer.

17. The electronic device of claim 16, wherein an area of the second sub-light-emitting layer is larger than the area of the charge generation layer.

18. The electronic device of claim 13, further comprising:
a first common layer disposed between the plurality of first electrodes and the first light-emitting layer and overlapping the first emission area, the second emission area and the third emission area; and
a second common layer disposed between the first light-emitting layer and the second electrode and overlapping the first emission area, the second emission area and the third emission area.

19. The electronic device of claim 18, wherein each of the second light-emitting layer and the third light-emitting layer is disposed between the first common layer and the second common layer, the second light-emitting layer comprises a second intermediate layer and a third sub-light-emitting layer, and the third light-emitting layer comprises a third intermediate layer and a fourth sub-light-emitting layer.

20. The electronic device of claim 19, wherein the second intermediate layer comprises a second sub-intermediate layer and a third sub-intermediate layer, and the third intermediate layer comprises a fourth sub-intermediate layer and a fifth sub-intermediate layer.
